(19) United States
(12) Patent Application Publication
(10) Pub. No.: US 2011/0164352 A1
(43) Pub. Date: Jul. 7, 2011

(54) DOUBLE SLIDING MECHANISM FOR USER DEVICES

(75) Inventors: Yawei Ma, San Diego, CA (US); Ichiro Yamada, Del Mar, CA (US)

(73) Assignee: SONY ERICSSON MOBILE COMMUNICATIONS AB, Lund (SE)

(21) Appl. No.: 12/683,608

(22) Filed: Jan. 7, 2010

(51) Int. Cl. H05K 7/00; H05K 5/02; H04M 1/00

(52) U.S. Cl. 361/679.01; 312/334.1; 455/575.4

(57) ABSTRACT

A sliding mechanism including a first base member including a first slider mechanism having a first range of motion; a second base member including a second slider mechanism having a second range of motion; and a synchronization linker that links the first range of motion associated with the first slider mechanism during a sliding operation and the second range of motion associated with the second slider mechanism during the sliding operation, wherein a coupling of the first range of motion and the second range of motion during the sliding operation causes the first base member to gradually arc away and tilt from the second base member.

### BACKGROUND

With the development of user devices, users may access and exchange information anywhere and anytime. Typically, these user devices offer users a variety of services and applications. For example, these user devices may provide telephone service, e-mail service, texting service, as well as provide other types of applications, such as, music and video applications, to permit users to listen and watch various types of multimedia.

In today's marketplace, developers provide users with a variety of styles for these user devices. For example, a user device may take the form of a candybar style, a clamshell style, or a slider style. The user device having a slider style comprises a slider mechanism to allow one portion of the user device to slide away from another portion of the user device. Depending on the slider mechanism, the user device may be slid into open and closed positions when in a portrait orientation, a landscape orientation, or both.

### SUMMARY

According to an exemplary implementation, a sliding mechanism may include a first base member including a first slider mechanism having a first range of motion; a second base member including a second slider mechanism having a second range of motion; and a synchronization linker that links the first range of motion associated with the first slider mechanism during a sliding operation and the second range of motion associated with the second slider mechanism during the sliding operation, wherein a coupling of the first range of motion and the second range of motion during the sliding operation causes the first base member to gradually arc away and tilt from the second base member.

Additionally, the first range of motion may be substantially linear with respect to the first base member.

Additionally, the second range of motion is arced with respect to an upper surface of the first base member.

Additionally, the first slider mechanism may comprise actuators for moving the synchronization linker during the sliding operation.

Additionally, the synchronization linker moves along a path associated with guides and the second slider mechanism protrudes through the guides to couple with the synchronization linker.

Additionally, the guides correspond to openings associated with the first base member and the openings have a substantially linear configuration.

Additionally, the second slider mechanism may comprise pins that move along a path associated with guides during the sliding operation.

Additionally, the guides may correspond to openings associated with the second base member and the openings have a curved configuration.

Additionally, the first base member is mounted to a first casing of a user device and the second base member is mounted to a second casing of the user device.

Additionally, the user device may comprise a communication device.

According to another implementation, a user device may comprise a first casing including a first slider mechanism having a first range of motion; a second casing including a second slider mechanism having a second range of motion; and a synchronization linker to couple the second slider mechanism to the first slider mechanism, wherein the synchronization linker links the first range of motion associated with the first slider mechanism during a sliding operation and the second range of motion associated with the second slider mechanism during the sliding operation, wherein a coupling of the first range of motion and the second range of motion causes the first casing to tilt upward and gradually arc away from the second casing when the user device transitions from a closed position to an open position.

Additionally, the user device may correspond to one of a cellular phone, a personal digital assistant, a data organizer device, a calculator, a picture capturing device, a video capturing device, a computer, a music playing device, a location-aware device, or a gaming device.

Additionally, the first slider mechanism may comprise a base member having openings that provide a path corresponding to the first range of motion; and actuators coupled to the base member and the synchronization linker for moving the synchronization linker during the sliding operation.

Additionally, the second slider mechanism may comprise a support member that protrudes through the openings to couple the second slider mechanism to the synchronization linker.

Additionally, the support member may provide a space between the base member and the synchronization linker to allow the actuators to swing as the synchronization linker moves during the sliding operation.

Additionally, the second slider mechanism may comprise pins that move along openings having a curved configuration.

Additionally, where one of the openings may have a different curved configuration than another one of the openings.

Additionally, where the second slider mechanism may comprise a base member to support the pins, and where the pins may be positioned symmetrically on ends of the base member.

Additionally, where the first range of motion may be substantially linear.

Additionally, where the first casing may be in a tilted position with respect to the second casing when the user device is in the open position.

### BRIEF DESCRIPTION OF THE DRAWINGS

The accompanying drawings, which are incorporated in and constitute a part of this specification, illustrate exemplary embodiments described herein and, together with the description, explain these exemplary embodiments. In the drawings:

FIG. 1 is a diagram illustrating an exemplary range of motion associated with an exemplary double sliding mechanism described herein;

FIG. 2 is a diagram of an exemplary user device in which one or more embodiments described herein may be implemented;

FIG. 3 is a diagram illustrating exemplary components of the user device;

FIGS. 4A-4C are diagrams illustrating an exemplary double sliding mechanism of the user device;

FIGS. 5A-5C are diagrams illustrating side views of the double sliding mechanism in different transitional positions as a sliding stroke causes the user device to transition from a closed position to an open position;

FIGS. 6A-6D are diagrams illustrating other views of the double sliding mechanism; and

FIG. 7 is a diagram illustrating arced surfaces of a first casing and a second casing.

### DETAILED DESCRIPTION

The following detailed description refers to the accompanying drawings. The same reference numbers in different drawings may identify the same or similar elements. Also, the following description does not limit the invention.

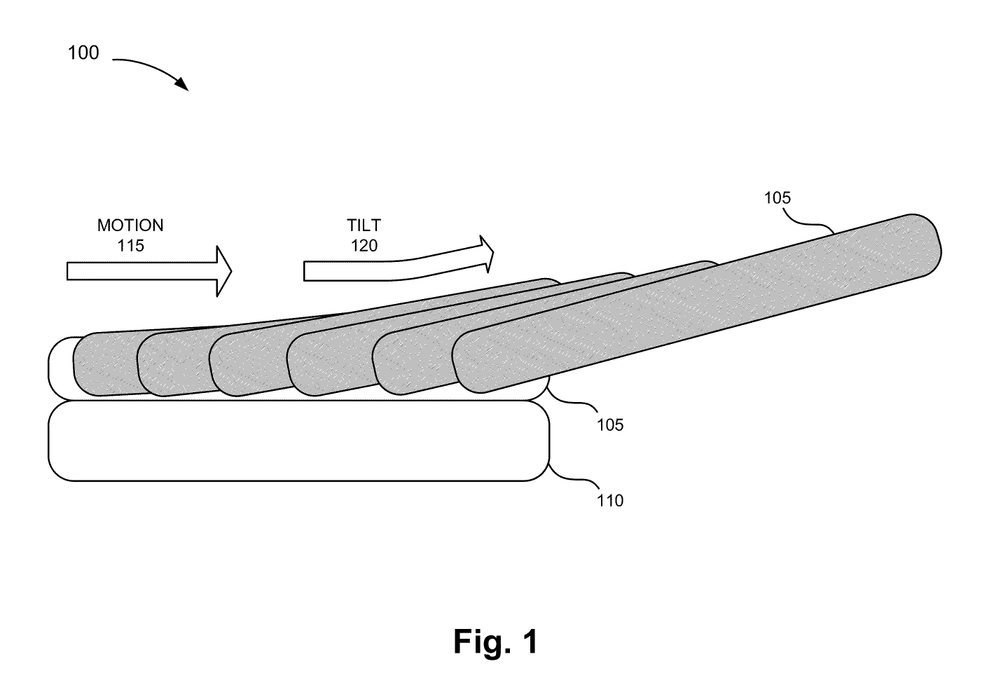

Embodiments described herein relate to a double sliding mechanism. The double sliding mechanism may allow for a multi-dimensional range of motion. In an exemplary embodiment, the double sliding mechanism may comprise a top slider and a bottom slider. The top slider may comprise a synchronization linker that couples the top slider and the bottom slider so that the top slider and the bottom slider cooperatively move to provide the multi-dimensional range of motion. FIG. 1 is a diagram illustrating an exemplary range of motion associated with an exemplary double sliding mechanism. As illustrated, a user device 100 may include a first casing 105 and a second casing 110. According to an exemplary opening motion, a user may initiate a sliding stroke in which first casing 105 may be placed in a motion 115 in which motion 115 may include a tilt 120. As illustrated, motion 115 and tilt 120 may be considered as parts of one continuous motion versus two disconnected motions. As will be described in greater detail, the synchronization linker may couple the top slider (e.g., included in first casing 105) with the bottom slider (e.g., included with second casing 110) to provide multiple axes of motion.

As a result of the foregoing, a length of the sliding stroke may be maximized when opening and closing user device 100. Additionally, or alternatively, the sliding stroke may cause first casing 105 of user device 100 to gradually rise up (or arc away) and tilt upward during the sliding stroke to avoid collision with other components associated with first casing 105 and/or second casing 110 of user device 100. This is in contrast to other approaches in which first casing 105 slides parallel to second casing 110, which could result in damage to components (e.g., a keypad, etc.) on a surface of second casing 110 and/or damage to components (e.g., a display, etc.) on a surface of first casing 105. Additionally, or alternatively, a thickness of user device 100 may be minimized. That is, in contrast to other approaches in which first casing 105 and/or second casing 110 may include arced surfaces that may increase an overall thickness of user device 100, in one or more embodiments described herein, first casing 105 and/or second casing 110 may not include arced surfaces.

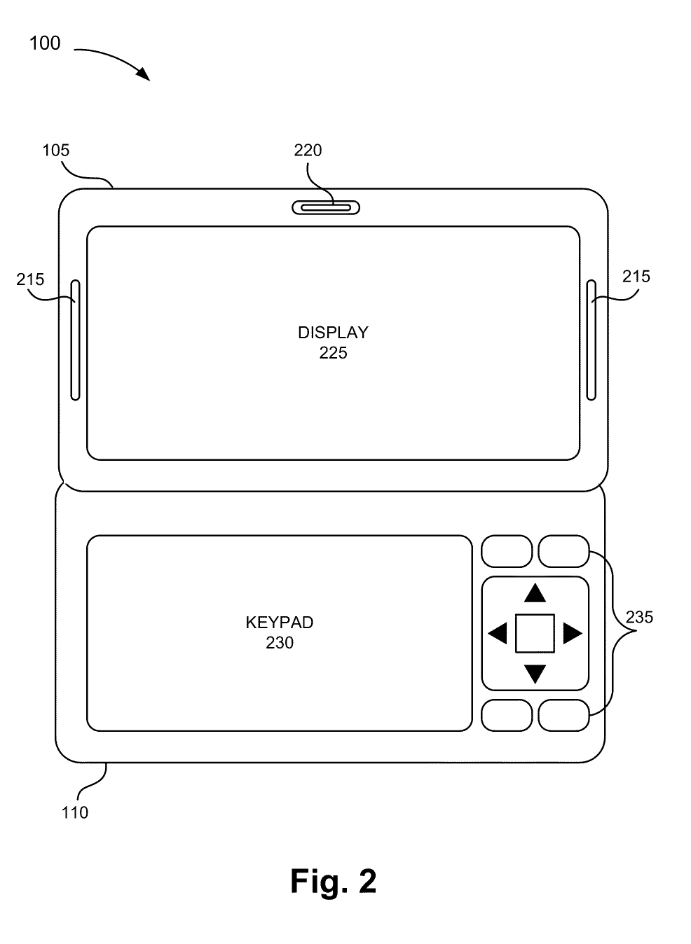

FIG. 2 is a diagram of an exemplary user device 100 in which one or more embodiments described herein may be implemented. The term “user device,” as used herein, is intended to be broadly interpreted to comprise a variety of devices. For example, user device 100 may comprise a portable device, a mobile device, a handheld device, or a stationary device. By way of example, but not limited thereto, user device 100 may comprise a telephone (e.g., a smart phone, a cellular phone, an Internet Protocol (IP) telephone, etc.), a personal digital assistant (PDA) device, a data organizer device, a calculator, a picture capturing device, a video capturing device, a computer, a music playing device, a multimedia playing device, a location-aware device (e.g., a Global Positioning System (GPS) device), a gaming device, and/or some other type of user device (e.g., an ashtray, an encasing, etc.).

As illustrated in FIG. 2, user device 100 may comprise a first casing 105, a second casing 110, speakers 215, a microphone 220, a display 225, a keypad 230, and special purpose keys 235. In other embodiments, user device 100 may comprise fewer components, additional components, different components, and/or a different arrangement of components than those illustrated in FIG. 2 and described herein. By way of example, but not limited thereto, in other embodiments user device 100 may not comprise speakers 215, microphone 220, keypad 230, and/or special purpose keys 235. Additionally, or alternatively, by way of example, but not limited thereto, in other embodiments, user device 100 may comprise a camera component or a touchpad. Additionally, or alternatively, although user device 100 is depicted as having a landscape configuration, in other embodiments, user device 100 may have a portrait configuration or some other type of configuration.

First casing 105 may comprise a structure to contain components of user device 100. For example, first casing 105 may be formed from plastic, metal, or some other material. First casing 105 may support speakers 215, microphone 220, and display 225.

Second casing 110 may comprise a structure to contain components of user device 100. For example, second casing 110 may be formed from plastic, metal, or some other material. Second casing 210 may support keypad 230 and special purpose keys 235.

Speakers 215 may transduce an electrical signal to a corresponding sound wave. For example, a user may listen to music or listen to a calling party through speakers 215. Microphone 220 may transduce a sound wave to a corresponding electrical signal. For example, a user may speak into microphone 220 during a telephone call or to execute a voice command.

Display 225 may operate as an output component. Additionally, in some implementations, display 225 may operate as an input component. For example, display 225 may comprise a touch-sensitive screen. In such instances, display 225 may correspond to a single-point input device (e.g., capable of sensing a single touch) or a multipoint input device (e.g., capable of sensing multiple touches that occur at the same time). Further, display 225 may implement a variety of sensing technologies, including but not limited to, capacitive sensing, surface acoustic wave sensing, resistive sensing, optical sensing, pressure sensing, infrared sensing, or gesture sensing. Display 225 may also comprise an auto-rotating function.

Display 225 may comprise a liquid crystal display (LCD), a plasma display panel (PDP), a field emission display (FED), a thin film transistor (TFT) display, or some other type of display technology. Display 225 may be capable of displaying text, pictures, and/or video. Display 225 may also be capable of displaying various images (e.g., icons, a keypad, etc.) that may be selected by a user to access various applications and/or enter data. Display 225 may operate as a viewfinder when user device 100 comprises a camera or a video capturing component.

Keypad 230 may provide input to user device 100. Keypad 230 may comprise a standard telephone keypad, a QWERTY keypad, and/or some other type of keypad (e.g., a calculator keypad, etc.). In exemplary implementation, one or more keys of keypad 230 may comprise a pushbutton. Special purpose keys 235 may provide input to user device 100. For example, special purpose keys 235 may provide a particular function (e.g., send, call, e-mail, etc.) and/or permit a user to select, navigate, etc.

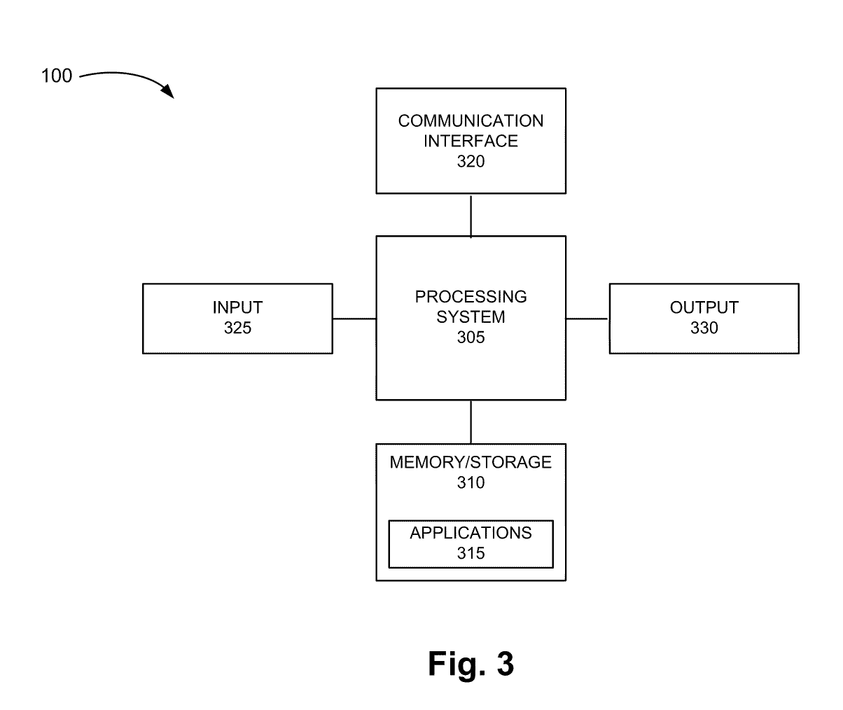

FIG. 3 is a diagram illustrating exemplary components of user device 100. As illustrated, user device 100 may comprise a processing system 305, a memory/storage 310 that may comprise applications 315, a communication interface 320, an input 325, and an output 330. In other embodiments, user device 100 may comprise fewer components, additional components, different components, or a different arrangement of components than those illustrated in FIG. 3 and described herein.

Processing system 305 may comprise one or multiple processors, microprocessors, data processors, co-processors, network processors, application specific integrated circuits (ASICs), controllers, programmable logic devices, chipsets, field programmable gate arrays (FPGAs), and/or some other component that may interpret and/or execute instructions and/or data. Processing system 305 may control the overall operation (or a portion thereof) of user device 100 based on, for example, an operating system and/or various applications (e.g., applications 315). Processing system 305 may access instructions from memory/storage 310, from other components of user device 100, and/or from a source external to user device 100 (e.g., a network or another device). Processing system 305 may provide for different operational modes associated with user device 100.

Memory/storage 310 may comprise one or multiple memories and/or one or more secondary storages. For example, memory/storage 310 may comprise a random access memory (RAM), a dynamic random access memory (DRAM), a read only memory (ROM), a programmable read only memory (PROM), a flash memory, and/or some other type of memory. Memory/storage 310 may comprise a hard disk (e.g., a magnetic disk, an optical disk, a magneto-optic disk, a solid state disk, etc.) or some other type of computer-readable medium, along with a corresponding drive. Memory/storage 310 may comprise a memory, a storage device, or storage component that is external to and/or removable from user device 100, such as, for example, a Universal Serial Bus (USB) memory stick, a hard disk, mass storage, off-line storage, etc.

The term “computer-readable medium,” as used herein, is intended to be broadly interpreted to comprise, for example, a memory, a secondary storage, a compact disc (CD), a digital versatile disc (DVD), or the like. The computer-readable medium may be implemented in a single device, in multiple devices, in a centralized manner, or in a distributed manner. Memory/storage 310 may store data, application(s), and/or instructions related to the operation of device 300.

Memory/storage 310 may store data, applications 315, and/or instructions related to the operation of user device 100. Applications 315 may comprise software that provides various services or functions. By way of example, but not limited thereto, applications 315 may comprise an e-mail application, a telephone application, a voice recognition application, a video application, a multi-media application, a music player application, a visual voicemail application, a contacts application, a data organizer application, a calendar application, an instant messaging application, a texting application, a web browsing application, a location-based application (e.g., a GPS-based application), a blogging application, and/or other types of applications (e.g., a word processing application, a spreadsheet application, etc.).

Communication interface 320 may permit user device 100 to communicate with other devices, networks, and/or systems. For example, communication interface 320 may comprise one or multiple wireless and/or wired communication interfaces. By way of example, but not limited thereto, communication interface 320 may comprise an Ethernet interface, a radio interface, a microwave interface, or some other type of wireless and/or wired interface. Communication interface 320 may comprise a transmitter and a receiver.

Input 325 may permit an input into user device 100. For example, input 325 may comprise microphone 220, display 225, keypad 230, a touchpad, a button, a switch, an input port, voice recognition logic, fingerprint recognition logic, a web cam, and/or some other type of visual, auditory, tactile, etc., input component. Output 335 may permit user device 100 to provide an output. For example, output 330 may comprise speakers 215, display 225, one or more light emitting diodes (LEDs), an output port, a vibratory mechanism, and/or some other type of visual, auditory, tactile, etc., output component.

User device 100 may perform operations in response to processing system 305 executing software instructions contained in a computer-readable medium, such as memory/storage 310. The software instructions may be read into memory/storage 310 from another computer-readable medium or from another device via communication interface 320. The software instructions contained in memory/storage 310 may cause processing system 305 to perform various processes. Alternatively, hardwired circuitry may be used in place of or in combination with software instructions to implement various processes.

### Exemplary Double Sliding Mechanism

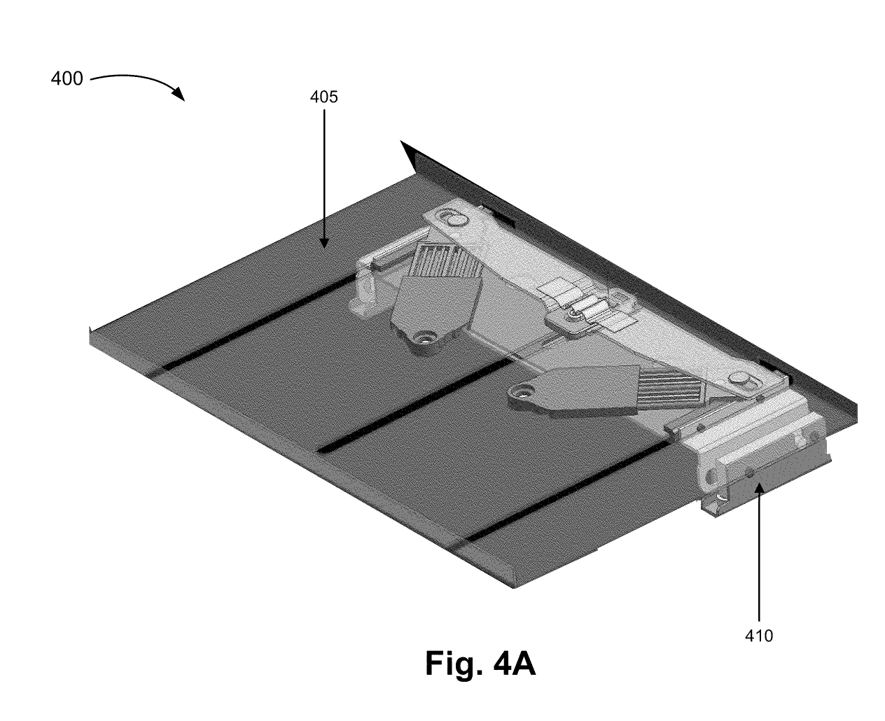

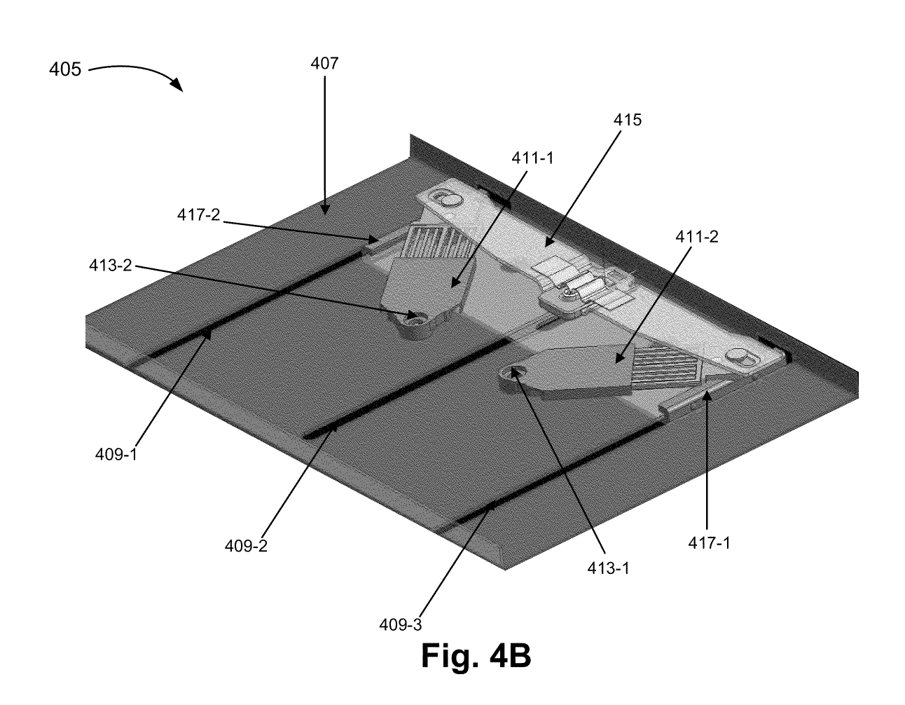

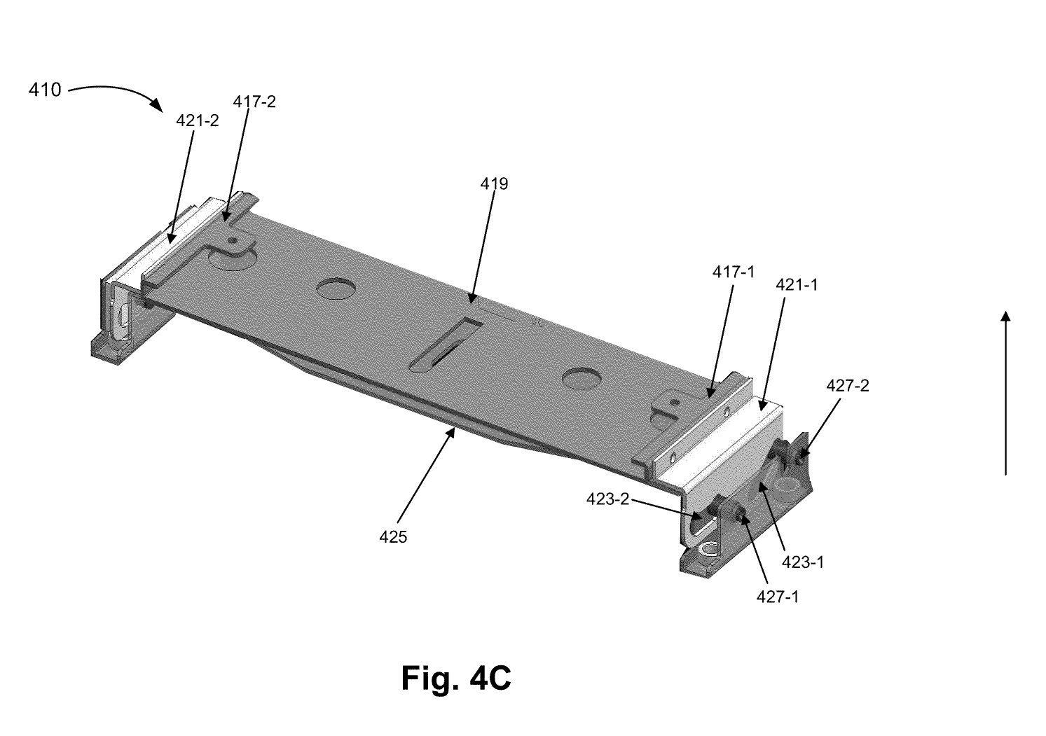

As previously described, user device 100 may include a double sliding mechanism. FIGS. 4A-4C are diagrams illustrating an exemplary double sliding mechanism 400. Referring to FIG. 4A, double sliding mechanism 400 may comprise a top slider 405 and a bottom slider 410. Top slider 405 and bottom slider 410 are coupled and provide for a sliding stroke having a multi-dimensional range of motion. In one or more exemplary embodiments, top slider 405 may be mounted to first casing 105 and bottom slider 410 may be mounted to second casing 110 of user device 100.

FIG. 4B is a diagram illustrating an exemplary top slider 405. As illustrated, top slider 405 may include a base member 407 having a planar configuration. Base member 407 may comprise guides 409-1 through 409-3 (referred to generally as guides 409 or guide 409). Guides 409 may correspond to openings in base member 407. In an exemplary implementation, guides 409 may have a linear configuration. Top slider 405 may also include actuators 411-1 and 411-2 (referred to generally as actuators 411 or actuator 411). Actuators 411 may include openings at one end to accept pivotal members 413-1 and 413-2 (referred to generally as pivotal members 413 or pivotal member 413). Pivotal members 413 may permit actuators 411 to swing and traverse along guides 409 during a sliding stroke.

A synchronization linker 415 may be coupled to another end of each actuator 411. As further illustrated, synchronization linker 415 may also be coupled to support members 417-1 and 417-2 (referred to generally as support members 417 or support member 417) of bottom slider 410. Support members 417 may protrude through guides 409 and provide space for actuators 411 to swing as synchronization linker 415 moves during the sliding stroke.

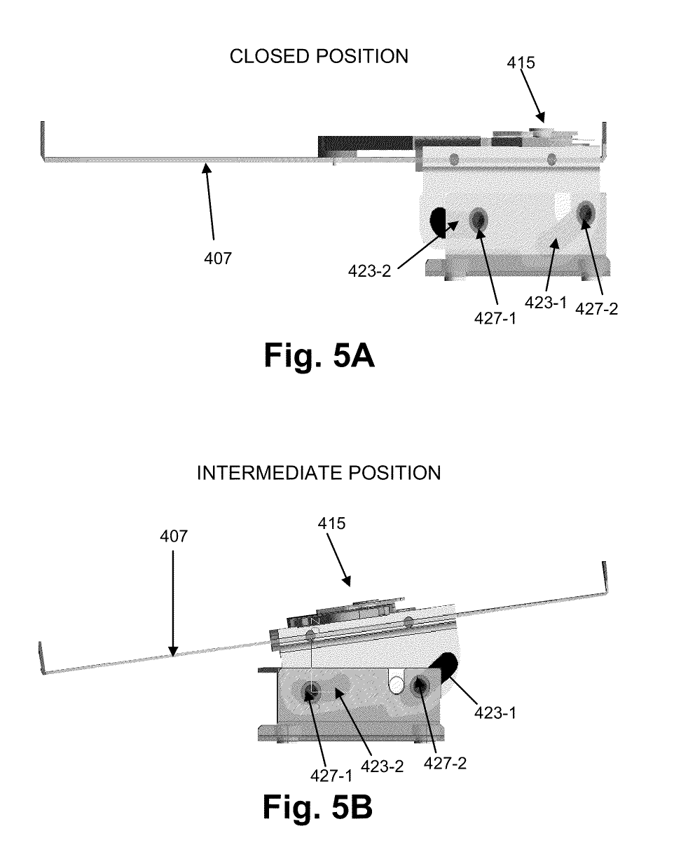

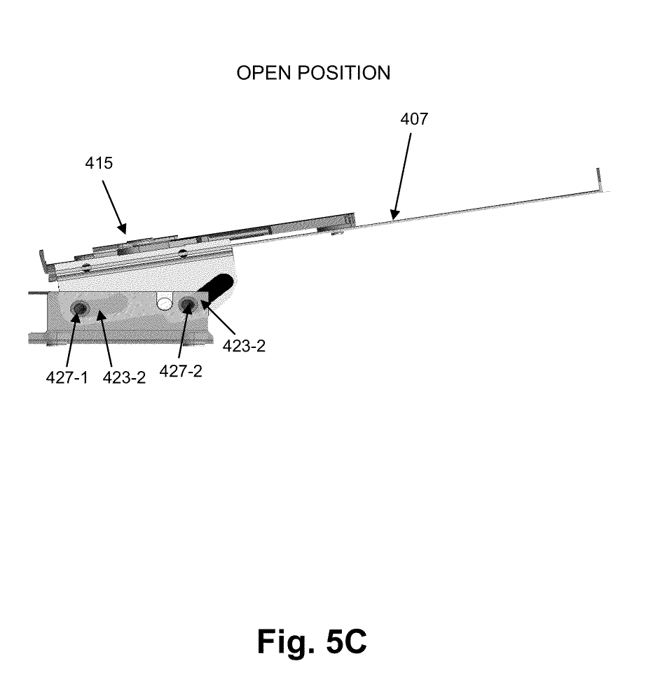

FIG. 4C is a diagram of an exemplary bottom slider 410. As previously mentioned, bottom slider 410 may include support members 417 that may be formed from a guide member 419. In symmetrical fashion, guide member 419 may be coupled to extenders 421-1 and 421-2 (referred to generally as extenders 421 or extender 421). Extenders 421 may each comprise guides 423-1 and 423-2 (referred to generally as guides 423 or guide 423). Guides 423 may correspond to openings in extenders 421. The shapes of guides 423 may be governed by a degree of tilt with which first casing 105 may reach during the sliding stroke. In an exemplary embodiment, first casing 105 may tilt between 8 degrees and 15 degrees, with respect to second casing 110, when user device 100 is in an open position. In other embodiments, the degree of tilt may be less than 8 degrees or more than 15 degrees. As further illustrated in FIGS. 5A-5C, in an exemplary embodiment, guides 423 may have a curved configuration. As further illustrated in FIGS. 5A-5C, guide 423-1 may have a different configuration than guide 423-2. A degree of tilt may be based on a curvature associated with the curved configuration(s) of guide(s) 423.

Referring back to FIG. 4C, bottom slider 410 may comprise a base member 425. Base member 425 may extend a length in excess of guide member 419 and extender 421. The excess length may permit pins 427-1 and 427-2 (referred to generally as pins 427 or pin 427) to protrude through guides 423. In an exemplary embodiment, end potions of base member 425 may have a “C” configuration such that pins 427 may couple and extend from one portion of base member 425 to another portion of base member 425.

FIGS. 5A-5C are diagrams illustrating side views of double sliding mechanism 400 in different transitional positions as a sliding stroke causes user device 100 to transition from a closed position to an open position. Referring to FIG. 5A, user device 100 may be in a closed position. In this position, actuators 411 of top slider 405 may be situated at one of end of guides 409 and pins 427 of bottom slider 410 may be situated at one end of guides 423.

Referring to FIG. 5B, as double sliding mechanism 400 transitions from the closed position to an intermediate position, actuators 411 may swing causing synchronization linker 415 to move toward a middle position of base member 407. Concurrently, pins 427 may move towards the other end of guides 423. In this way, as previously described, synchronization linker 415 may provide that top slider 405 and bottom slider 410 move in synchronization during the sliding stroke providing a multi-dimensional range of motion. As further shown in FIG. 5B, base member 407 may be in a tilted position with respect to its previous position illustrated in FIG. 5A.

Referring to FIG. 5C, as double sliding mechanism 400 transitions from the intermediate position to an open position, actuators 411 may further swing causing synchronization linker 415 to move from the middle position of base member 407 to the other end of base member 407. Concurrently, pins 427 may move to the far end of guides 423 resulting in a maximum tilt angle of base member 407 with respect to an upper surface of bottom slider 410. As further shown in FIG. 5C, base member 407 may be in a tilted position with respect to its previous position illustrated in FIG. 5B. In this way, from the closed position to the open position, synchronization linker 415 may link a first range of motion associated with top slider 405 with a second range of motion associated with bottom slider 410 so that the first range of motion and the second range of motion act in concert as one motion. The one motion corresponding to an arcing motion that provides the tilt of first casing 105. Further, as previously described, the arcing motion may cause first casing 105 to gradually rise up (or to gradually arc away) and tilt upward from second casing 110, which may minimize damage to components (e.g., display 225, keypad 230, etc.) associated with first casing 105 and second casing 110.

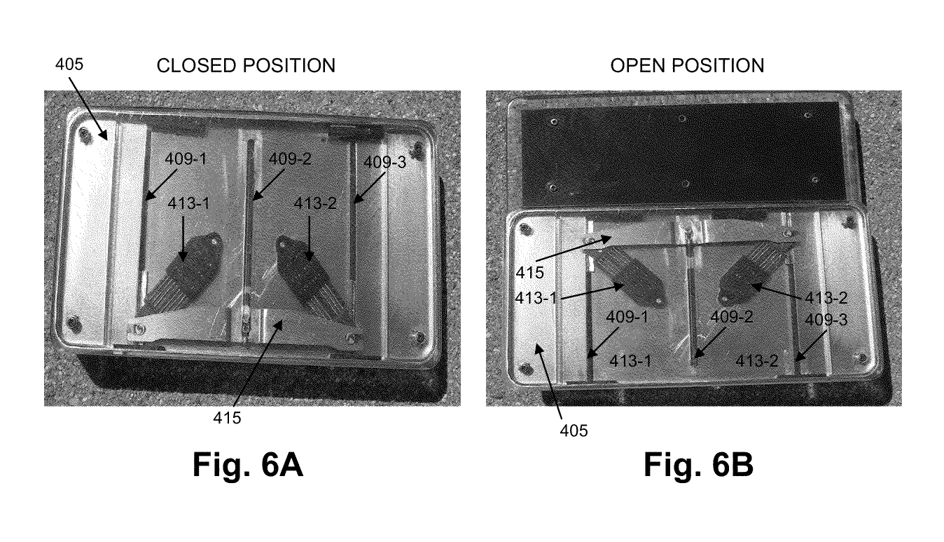

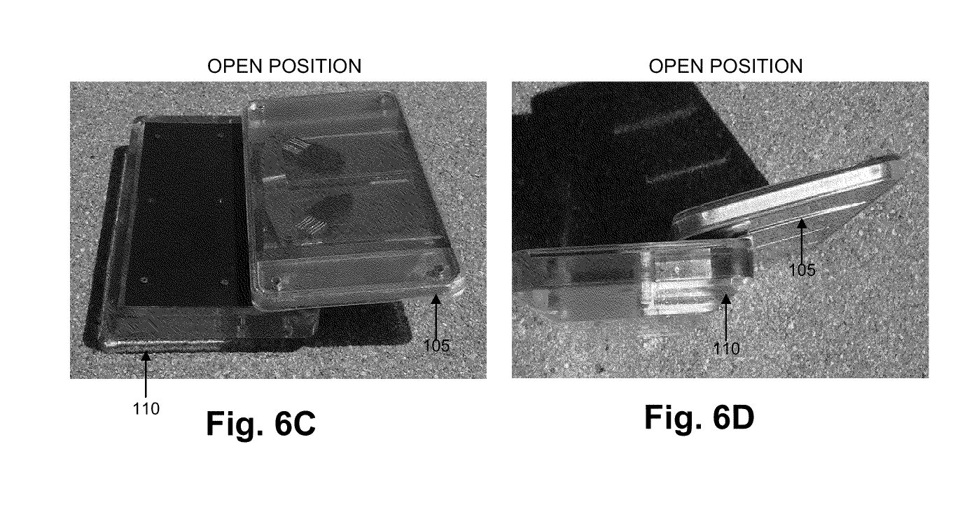

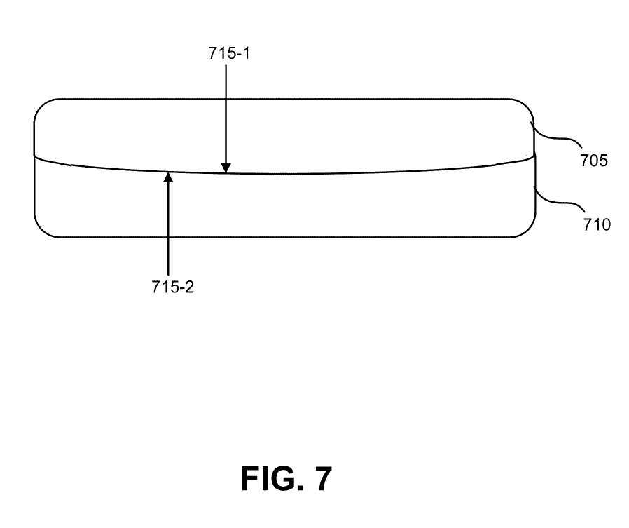

FIGS. 6A-6D are diagrams illustrating other views of double sliding mechanism 400. As illustrated in FIGS. 6A and 6B, double sliding mechanism 400 is shown in a closed position and an open position, respectively. FIG. 6C illustrates double sliding mechanism 400 in an open position from an elevated top-side view perspective. FIG. 6D illustrates double sliding mechanism 400 in an open position from a side view perspective. In the exemplary embodiments illustrated in FIGS. 6C and 6D, it will be appreciated that first casing 105 and second casing 110 may not include arced surfaces. Rather, inside surfaces associated with first casing 105 and second casing 110 may be relatively flat, which may reduce an overall thickness of user device 100. This is in contrast to other approaches in which first casing 705 and second casing 710 may include arced surfaces 715-1 and 715-2, as illustrated in FIG. 7, which may yield an increase in an overall thickness of a user device.

### CONCLUSION

The foregoing description of implementations provides illustration, but is not intended to be exhaustive or to limit the implementations to the precise form disclosed. Modifications and variations are possible in light of the above teachings or may be acquired from practice of the teachings.

The terms “comprise,” “comprises,” “comprising”, as well as derivatives thereof (e.g., include, etc.), when used in the specification is taken to specify the presence of stated features, integers, steps, or components but does not preclude the presence or addition of one or more other features, integers, steps, components, or groups thereof. In other words, these terms and derivatives thereof mean inclusion without limitation.

The terms “couple,” “couples,” “coupled”, etc., as well as derivatives thereof, may include a direct connection or an indirect connection between two or more components.

Spatially relative terms, such as “top,” “bottom,” “up,” “upward,” and the like, may be used herein for ease of description to describe one element's or feature's relationship to another element or feature as illustrated in the figures. It will be understood that the spatially relative terms are intended to encompass different orientations of the user device in use or operation, in addition to the use or the operation depicted in the figures. For example, if the user device in the figure is turned over or oriented in a different manner (e.g., rotated at 90 degrees or at some other orientation), the spatially relative terms used herein should be interpreted accordingly.

The article “a,” “an,” and “the” are intended to mean one or more items. Further, the phrase “based on” is intended to mean “based, at least in part, on” unless explicitly stated otherwise. The term “and/or” is intended to mean any and all combinations of one or more of the listed items.

No element, act, or instruction used in the present application should be construed as critical or essential to the implementations described herein unless explicitly described as such.

What is claimed is:

1. A sliding mechanism comprising:
a first base member including a first slider mechanism having a first range of motion;
a second base member including a second slider mechanism having a second range of motion; and
a synchronization linker that links the first range of motion associated with the first slider mechanism during a sliding operation and the second range of motion associated with the second slider mechanism during the sliding operation, wherein a coupling of the first range of motion and the second range of motion during the sliding operation causes the first base member to gradually arc away and tilt from the second base member.

2. The sliding mechanism of claim 1, wherein the first range of motion is substantially linear with respect to the first base member.

3. The sliding mechanism of claim 2, wherein the second range of motion is arced with respect to an upper surface of the first base member.

4. The sliding mechanism of claim 1, wherein the first slider mechanism comprises actuators for moving the synchronization linker during the sliding operation.

5. The sliding mechanism of claim 4, wherein the synchronization linker moves along a path associated with guides and the second slider mechanism protrudes through the guides to couple with the synchronization linker.

6. The sliding mechanism of claim 5, wherein the guides correspond to openings associated with the first base member and the openings have a substantially linear configuration.

7. The sliding mechanism of claim 1, wherein the second slider mechanism comprises pins that move along a path associated with guides during the sliding operation.

8. The sliding mechanism of claim 7, wherein the guides correspond to openings associated with the second base member and the openings have a curved configuration.

9. The sliding mechanism of claim 1, wherein the first base member is mounted to a first casing of a user device and the second base member is mounted to a second casing of the user device.

10. The sliding mechanism of claim 9, wherein the user device comprises a communication device.

11. A user device comprising:
a first casing including a first slider mechanism having a first range of motion;
a second casing including a second slider mechanism having a second range of motion; and
a synchronization linker to couple the second slider mechanism to the first slider mechanism, wherein the synchronization linker links the first range of motion associated with the first slider mechanism during a sliding operation and the second range of motion associated with the second slider mechanism during the sliding operation, wherein a coupling of the first range of motion and the second range of motion causes the first casing to tilt upward and gradually arc away from the second casing when the user device transitions from a closed position to an open position.

12. The user device of claim 11, wherein the user device corresponds to one of a cellular phone, a personal digital assistant, a data organizer device, a calculator, a picture capturing device, a video capturing device, a computer, a music playing device, a location-aware device, or a gaming device.

13. The user device of claim 11, wherein the first slider mechanism comprises:
a base member having openings that provide a path corresponding to the first range of motion; and
actuators coupled to the base member and the synchronization linker for moving the synchronization linker during the sliding operation.

14. The user device of claim 13, wherein the second slider mechanism comprises:
a support member that protrudes through the openings to couple the second slider mechanism to the synchronization linker.

15. The user device of claim 14, wherein the support member provides a space between the base member and the synchronization linker to allow the actuators to swing as the synchronization linker moves during the sliding operation.

16. The user device of claim 11, wherein the second slider mechanism comprises pins that move along openings having a curved configuration.

17. The user device of claim 16, wherein one of the openings has a different curved configuration than another one of the openings.

18. The user device of claim 16, wherein the second slider mechanism comprises:
a base member to support the pins, wherein the pins are positioned symmetrically on ends of the base member.

19. The user device of claim 11, wherein the first range of motion is substantially linear.

20. The user device of claim 11, wherein the first casing is in a tilted position with respect to the second casing when the user device is in the open position.
